(19) United States
(12) Patent Application Publication
(10) Pub. No.: US 2014/0153204 A1
(43) Pub. Date: Jun. 5, 2014

(54) ELECTRONIC COMPONENT EMBEDDED PRINTING CIRCUIT BOARD AND METHOD FOR MANUFACTURING THE SAME

(71) Applicant: SAMSUNG ELECTRO-MECHANICS CO., LTD., Gyeonggi-do (KR)

(72) Inventors: Moon Il Kim, Gyeonggi-do (KR); Yong Soon Jang, Gyeonggi-do (KR); Byoung Hwa Lee, Gyeonggi-do (KR); Hyun Kyung Park, Gyeonggi-do (KR); Soon Jin Cho, Gyeonggi-do (KR)

(73) Assignee: Samsung Electro-Mechanics Co., Ltd., Gyeonggi-do (KR)

(21) Appl. No.: 13/776,612

(22) Filed: Feb. 25, 2013

(30) Foreign Application Priority Data
Nov. 30, 2012 (KR) 10-2012-0138044

(51) Int. Cl. H05K 1/18; H05K 3/32

(52) U.S. Cl. CPC H05K 1/183; H05K 3/321
USPC 361/762; 361/761; 29/837

(57) ABSTRACT

The present invention relates to an electronic component embedded printed circuit board and a method for manufacturing the same.

An electronic component embedded printed circuit board of the present invention includes a core having a cavity; an electronic component inserted in the cavity and having a bonding coating layer on an outer peripheral surface; insulating layers laminated on and under the core and in contact with the bonding coating layer; and circuit patterns provided on the insulating layers.

### CROSS-REFERENCE TO RELATED APPLICATIONS

Claim and incorporate by reference domestic priority application and foreign priority application as follows:

This application claims the benefit under 35 U.S.C. Section 119 of Korean Patent Application Serial No. 10-2012-0138044, entitled filed Nov. 30, 2012, which is hereby incorporated by reference in its entirety into this application.

### BACKGROUND OF THE INVENTION

1. Field of the Invention

The present invention relates to an electronic component embedded printed circuit board and a method for manufacturing the same.

2. Description of the Related Art

As the size of substrates is limited and multiple functions of electronic devices are required with the miniaturization and thinning of the IT electronic devices including mobile phones, it is required to mount electronic components for implementing more functions in the limited area of the substrate.

However, as the size of the substrate is limited, since it is not possible to secure a sufficient mounting area of the electronic components, there is a demand for a technology of inserting electronic components like active devices, such as ICs and semiconductor chips, and passive devices in a substrate. In recent times, a technology of embedding active devices and passive devices in the same layer or a technology of embedding active devices and passive devices in a substrate by stacking them has been developed.

Typically, a method for manufacturing an electronic component embedded printed circuit board forms a cavity in a core of a substrate and inserts electronic components such as various devices, ICs, and semiconductor chips in the cavity. After that, a resin material such as prepreg is applied inside the cavity and on the core in which the electronic component is inserted to form an insulating layer as well as to fix the electronic component, and a via hole or a through hole is formed in the insulating layer and a circuit is formed by plating to allow the electronic component to conduct with the outside of the substrate.

At this time, a circuit pattern is formed inside and on the via hole or the through hole by plating to be used as an electrical connection means with the electronic component embedded in the substrate, and a multilayer printed circuit board in which the electronic component is embedded can be manufactured by sequentially laminating the insulating layer on upper and lower surfaces of the substrate.

In the conventional electronic component embedded printed circuit board like this, since soldering and reflow processes are repeated in every manufacturing process, a high temperature heat is applied to the laminate, and warpage of the substrate may occur whenever heating the laminate at high temperature. At this time, as the electronic component embedded in the substrate is made of a material having a different coefficient of thermal expansion (CTE) from the insulating layer bonded to the outside thereof, stress is concentrated on the bonding interface with the insulating layer due to repetition of the warpage of the substrate in every heating process, and as the process proceeds, delamination or lifting of the bonding interface occurs due to thermal shock.

### RELATED ART DOCUMENT

### Patent Document

Patent Document 1: Korean Patent Laid-open Publication No. 2012-0071938

### SUMMARY OF THE INVENTION

The present invention has been invented in order to overcome the above-described problems and it is, therefore, an object of the present invention to provide an electronic component embedded printed circuit board with improved mechanical characteristics and reliability.

It is another object of the present invention to provide a method for manufacturing an electronic component embedded printed circuit board with improved mechanical characteristics and reliability.

In accordance with one aspect of the present invention to achieve the object, there is provided an electronic component embedded printed circuit board including: a core having a cavity; an electronic component inserted in the cavity and having a bonding coating layer on an outer peripheral surface; insulating layers laminated on and under the core and in contact with the bonding coating layer; and circuit patterns provided on the insulating layers.

At this time, the electronic component may include external electrodes provided on both sides and a main body provided between the external electrodes, and the bonding coating layer may be formed over the entire surface along the external electrodes and the main body or on a surface of the main body except the external electrodes.

Further, the bonding coating layer may include a coupling agent interposed between different kinds of materials to reinforce a bonding force, and the coupling agent may include silane containing silicon (Si) atoms and organic functional groups. And, the silane may include at least one selected from the group consisting of amino silane, epoxy silane, and vinyl silane.

Further, the silane may be used by being mixed with ethanol.

And, a via may be further included inside the insulating layer to electrically connect the circuit pattern and the external electrode, the insulating layer may fill a space between the cavity and the electronic component, and circuit layers of a predetermined pattern may be formed on upper and lower surfaces of the core to be electrically connected through a through hole.

Meanwhile, in accordance with another aspect of the present invention to achieve the object, there is provided a method for manufacturing an electronic component embedded printed circuit board, including the steps of: forming a through hole-shaped cavity in a core and attaching a carrier to a lower surface of the core; inserting an electronic component having a bonding coating layer on an outer peripheral surface in the cavity; forming an upper insulating layer on the core in which the electronic component is embedded; removing the carrier attached to the lower surface of the core and reversing the core; forming a lower insulating layer on an opposite surface of the core on which the upper insulating layer is formed; and forming circuit patterns on the upper and lower insulating layers to be electrically connected to the electronic component through a via.

And, in accordance with another aspect of the present invention to achieve the object, there is provided a method for manufacturing an electronic component embedded printed circuit board, including the steps of: forming a through hole-shaped cavity in a core and attaching a carrier to a lower surface of the core; inserting an electronic component in the cavity; forming a bonding coating layer on the electronic component inserted in the cavity; forming an upper insulating layer on the core in which the electronic component is embedded in the cavity; removing the carrier attached to the lower surface of the core and reversing the core; forming the bonding coating layer on a surface of the electronic component exposed on the cavity of the core, where the bonding coating layer is not formed; forming a lower insulating layer on an opposite surface of the core on which the upper insulating layer is formed; and forming circuit patterns on the upper and lower insulating layers to be electrically connected to the electronic component through a via.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a cross-sectional view of an electronic component embedded printed circuit board in accordance with an embodiment of the present invention;

FIG. 2 is a cross-sectional view of an electronic component embedded printed circuit board in accordance with another embodiment of the present invention;

FIGS. 3A-3E are process diagrams showing a process of manufacturing an electronic component embedded printed circuit board in accordance with an embodiment of the present invention;

FIGS. 4A-4G are process diagrams showing a process of manufacturing an electronic component embedded printed circuit board in accordance with another embodiment of the present invention;

FIG. 5 is a graph of evaluation of adhesion between an electronic component and an insulating layer (prepreg) applied to the electronic component embedded printed circuit board in accordance with the present invention;

FIG. 6 is a schematic diagram of a bending evaluation test of the electronic component embedded printed circuit board in accordance with the present invention; and

FIGS. 7A-7B show comparison photographs of a normal product in which the electronic component and the insulating layer aren't delaminated and a defective product in which the electronic component and the insulating layer are delaminated after the bending test of the electronic component embedded printed circuit board.

### DETAILED DESCRIPTION OF THE PREFERABLE EMBODIMENTS

A matter regarding to an operational effect including a technical configuration for an object of an electronic component embedded printed circuit board and a method of manufacturing the same in accordance with the present invention will be clearly appreciated through the following detailed description with reference to the accompanying drawings showing preferable embodiments of the present invention.

Electronic Component Embedded Printed Circuit Board

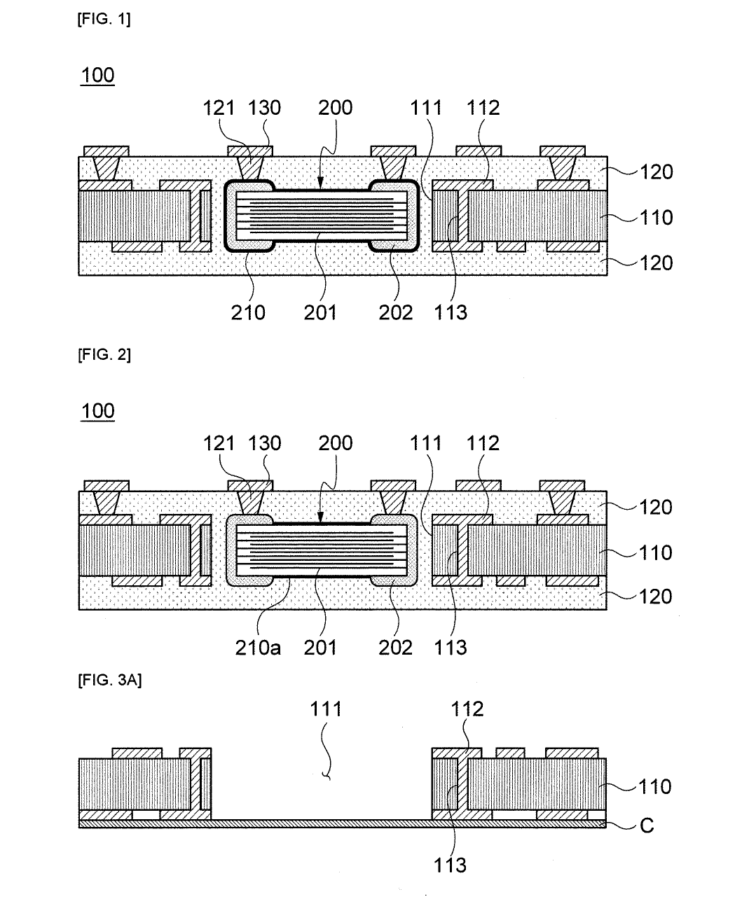

First, FIG. 1 is a cross-sectional view of an electronic component embedded printed circuit board in accordance with the present invention.

As shown, in an electronic component embedded printed circuit board 100 in accordance with the present invention, an electronic component 200 may be embedded inside a core 110 having a cavity 111, insulating layers 120 may be laminated on and under the core 110, and a bonding coating layer 210 may be formed on an outer peripheral surface of the electronic component 200.

In the electronic component embedded printed circuit board 100, although it is shown that the electronic component 200 embedded in the core 110 is embedded in one place, it is not limited thereto. The electronic component 200 may be embedded in a printed circuit board of each unit at regular intervals, and one or more electronic components 200 may be embedded according to the type of the embedded electronic component.

The cavity 111 may be formed in the core 110, which is positioned in the center of the electronic component embedded printed circuit board 100, in the shape of a through hole, and the cavity 111 may be formed by laser processing or drilling using CNC. At this time, it is preferred that the cavity 111 is formed to have a width equal to or greater than that of the electronic component 200 inserted therein.

Further, circuit layers 112 may be formed on upper and lower surfaces of the core 111 in a predetermined pattern, respectively, and the respective circuit layers 112 may be electrically connected through a via or a through hole 113 passing through the core 110. At this time, the core 110 may be generally made of an insulating material but may be made of a metal material such as aluminum to improve heat radiation efficiency of a substrate. When forming a metal core, an insulating layer should be further formed to prevent a short before formation of a circuit layer.

Meanwhile, the electronic component 200 is inserted in the cavity 111 of the core 110. The electronic component 200 may be an active device such as IC, semiconductor chip, or CPU in addition to a passive device such as MLCC or LTCC. At this time, it is preferred that a height of the electronic component is equal to that of the core.

Here, describing the electronic component 200 by taking an MLCC shown in the drawing as an example, an internal electrode may be formed in a main body 201, positive and negative external electrodes 202 may be formed on both sides of the main body 201, and the external electrodes 202 on the both sides may be physically and electrically connected to external circuits, respectively.

The bonding coating layer 210 may be formed on the outer peripheral surface of the electronic component 200. The bonding coating layer 210 may be made of a material containing silicon (Si) atoms and organic functional groups, and typically, silane may be used. The bonding coating layer 210 serves as a chemical coupling agent that improves bonding performance between different kinds of materials of the insulating layer 120 formed on the outer peripheral surface of the electronic component 200 and the both surfaces of the core 110 and prevents delamination and lifting of the insulating layer regardless of warpage and thermal shock repeated when processing the printed circuit board by reinforcing adhesion of the insulating layer 120 on the outer peripheral surface of the electronic component 200.

The bonding coating layer 210 may be formed only on the outside of the main body 201 of the electronic component 200, that is, the MLCC and may be formed on the entire outer peripheral surface of the electronic component 200 including outer peripheral surfaces of the external electrodes 202 provided on the both sides of the main body 201 according to a forming method thereof.

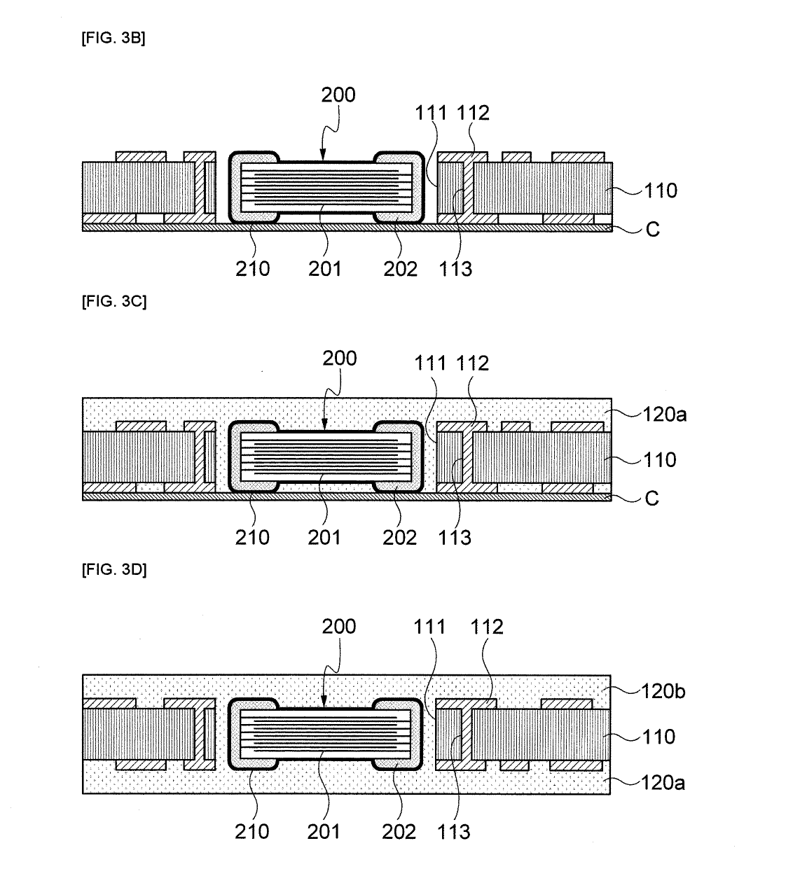

Here, the method of forming the bonding coating layer 210 on the electronic component 200 embedded in the cavity 111 of the core 110 may be various. Typically, the bonding coating layer 210 may be formed on the outer peripheral surface of the electronic component 200 by dipping the electronic component 200 in a silane solution and drying the electronic component 200 before embedding the electronic component 200 in the core 110 or the bonding coating layer 210 may be formed by embedding the electronic component 200 in the core 110 first, applying the silane solution on the surface of the electronic component 200 through printing, spraying, or dispensing, and drying the electronic component 200. At this time, when forming the bonding coating layer 210 on the outer peripheral surface of the electronic component 200 by dipping first, the bonding coating layer 210 may be formed after forming the external electrode 202 in the electronic component 200 or the bonding coating layer 210 may be formed on the outer peripheral surface of the main body 201 before forming the external electrode 202 and then the external electrode 202 may be formed. Therefore, when forming the bonding coating layer 210 before forming the external electrode 202, the bonding coating layer 210a may be formed only on the outside of the main body 201 between the external electrodes 202 of the electronic component 200 as shown in FIG. 2.

The insulating layers 120 may be respectively formed on and under the core 110 in which the electronic component 200 is embedded. The insulating layer 120 may be formed by laminating and curing an insulating material, that is, an insulating resin material such as prepreg. A portion in contact with the outer peripheral surface of the electronic component 200 when laminating and curing the insulating layer 120 may be firmly adhered to the insulating layer 120 through the bonding coating layer 210 formed in the shape of a thin film or absorbed on the outer peripheral surface of the electronic component 200. At this time, when the bonding coating layer 210 is also formed on the surface of the both external electrodes 202 of the electronic component 200, the both surfaces of the electronic component 200 may be also closely coupled with the insulating layer 120.

A plurality of vias 121 may be formed in the insulating layer 120. The via 121 may be formed by laser processing or drilling using CNC similarly to the cavity 111 formed in the core 110. A circuit pattern 130, which is electrically connected to the electronic component 200, may be formed by forming a plating layer on the upper surface of the insulating layer 120 including the via after forming the via 121 and etching the plating layer.

The electronic component embedded printed circuit board 100 configured like this can improve bonding performance between the outer peripheral surface of the electronic component 200 and the insulating layer 120 by interposing the bonding coating layer 210 on a contact interface of the surface of the electronic component 200 embedded in the core 110 and the insulating layers 120 formed on and under the core 110.

Embodiment of Method for Manufacturing Electronic Component Embedded Printed Circuit Board

A method for manufacturing the electronic component embedded printed circuit board of the present invention configured as above will be described with reference to the following drawings.

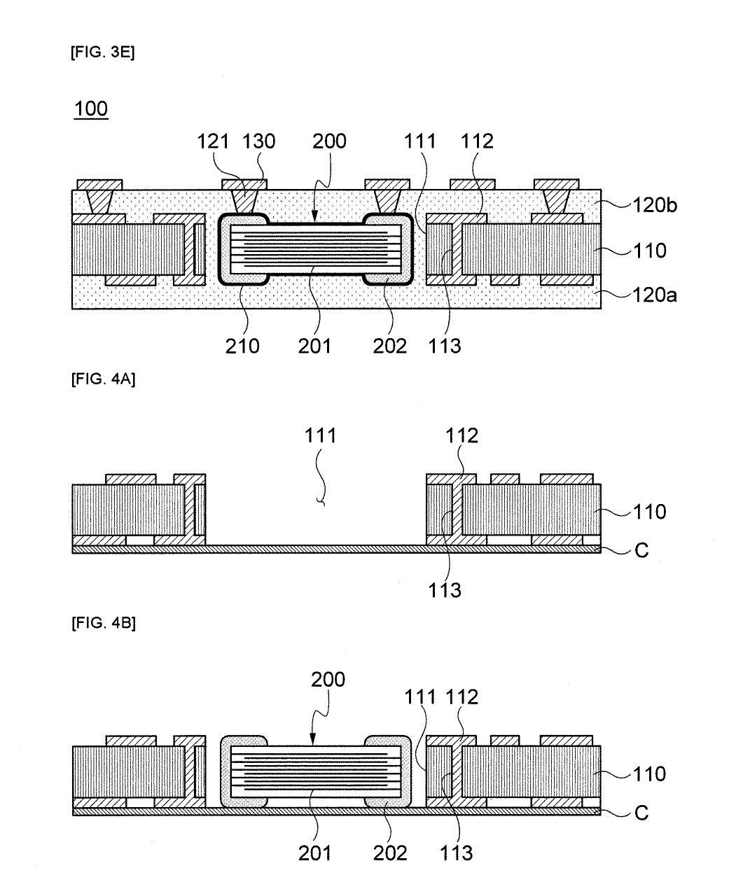

First, FIG. 3 is a process diagram showing a process of manufacturing an electronic component embedded printed circuit board in accordance with an embodiment of the present invention.

First, as shown in FIG. 3a, a cavity 111 is formed in a core 110, which is made of an insulating material, in the shape of a through hole. The cavity 111 may be formed by laser processing or drilling. The cavity 111 is formed with a predetermined size and may be formed with a width equal to or greater than a width of an electronic component 200 inserted therein.

Additionally, a carrier C may be attached to a lower surface of the core 110. The carrier C, which is a member for fixing a position of the electronic component 200 when inserting the electronic component 200 in the cavity 111 formed as a through hole, prevents the electronic component 200 from being separated from the cavity 111 and temporarily fixes the electronic component 200 by an adhesive member applied on an upper surface thereof.

Next, the electronic component 200 is inserted in the cavity 111 of the core 110 to be positioned on the carrier C. It is preferred that the electronic component 200 is an electronic component having the same height as the thickness of the core 110. When the height of the electronic component 200 is higher than the thickness of the core 110, it is needed to increase the thickness of the core 110 to make the same height.

Meanwhile, a bonding coating layer 210 is applied on an outer peripheral surface of the electronic component 200 before inserting the electronic component 200 in the core 110 and cured. The bonding coating layer 210 may be formed on the entire or a portion of the outer peripheral surface of the electronic component 200. That is, describing with reference to FIGS. 1 to 3, the bonding coating layer 210 may be formed only on the surface of a main body 201 of the electronic component made of a dielectric or on the entire outer peripheral surface of the electronic component to surround the outside of the electronic component 200 including the main body 201 and external electrodes 202.

At this time, the bonding coating layer 210 is a material for chemically coupling an organic material and an inorganic material which are different kinds of materials and may include silane containing silicon atoms and organic functional groups coupled thereto. Silane is a monomer and there are various types of products according to organic groups coupled to Si—O that are mainly used for the purpose of processing various powder and increasing adhesion of a resin. Particularly, as the bonding coating layer 210 is formed of silane on the surface of an MLCC, which is formed by sintering powder, as the electronic component applied to the present embodiment, it is possible to increase adhesion between the surface of the electronic component 200 and the inorganic material, water repellency, and resin flow.

Here, in forming the bonding coating layer 210 on the surface of the electronic component 200, when forming the bonding coating layer 210 only on the surface of the main body 201 of the electronic component 200, the bonding coating layer 210 is formed only on the exposed portions of the upper and lower surfaces of the main body 201 as shown in FIG. 2 by dipping the main body 201 of the electronic component 200 in a silane solution to form the bonding coating layer 210 on the outer peripheral surface of the main body 201 in a state in which dielectrics having internal electrodes are laminated before forming the external electrodes 202 on the outer peripheral surface of the main body 201 of the electronic component 200 and then forming the external electrodes 202 on the both sides of the main body 201 on which the bonding coating layer 210 is formed. Further, when forming the bonding coating layer 210 on the entire outer peripheral surface of the electronic component 200, the bonding coating layer 210 is formed on the entire outer peripheral surface of the electronic component 200 by forming the external electrodes 202 on the both sides of the main body of the electronic component 200 and dipping the main body 201 having the external electrodes 202 in a silane solution. At this time, the silane solution may be a solution in which silane and ethanol are mixed, and the bonding coating layer 210 may be formed on the surface of the electronic component 200 by depositing the electronic component in the silane solution for 10 minutes, taking out the electronic component from the silane solution, and heating the electronic component at a temperature of 100° C. in an oven to cure the silane solution.

Next, as in FIG. 3c, an upper insulating layer 120a is formed on the core 110 in which the electronic component 200 is embedded. The upper insulating layer 120a may be formed by laminating an insulating material and cured by heating and compressing the insulating material. When heating and compressing the insulating material, some of the insulating material is introduced into a space between the cavity 111 of the core 110 and the electronic component 200 and cured to fix the electronic component 200. Apart from this, a separate adhesive may be injected between the electronic component 200 and a sidewall of the cavity 111 before the formation of the upper insulating layer 120a to fix the electronic component 200.

And, when the lamination of the upper insulating layer 120a is completed, the carrier C attached to the lower surface of the core 110 is removed. After that, as in FIG. 3d, the core 110 is reversed, and a lower insulating layer 120b is laminated on an opposite surface of the core 110 on which the upper insulating layer 120a is formed in the same manner as the upper insulating layer 120a and cured by heating and compression to complete the formation of the insulating layers 120a and 120b as in FIG. 3d.

Finally, as in FIG. 3e, a via hole 121 is formed in the upper and lower insulating layers 120a and 120b, a plating layer is formed inside the via hole 121 and on the insulating layers 120a and 120b, and a circuit pattern 130 is formed by etching the plating layer to complete the manufacture of the electronic component embedded printed circuit board.

Another Embodiment of Method for Manufacturing Electronic Component Embedded Printed Circuit Board

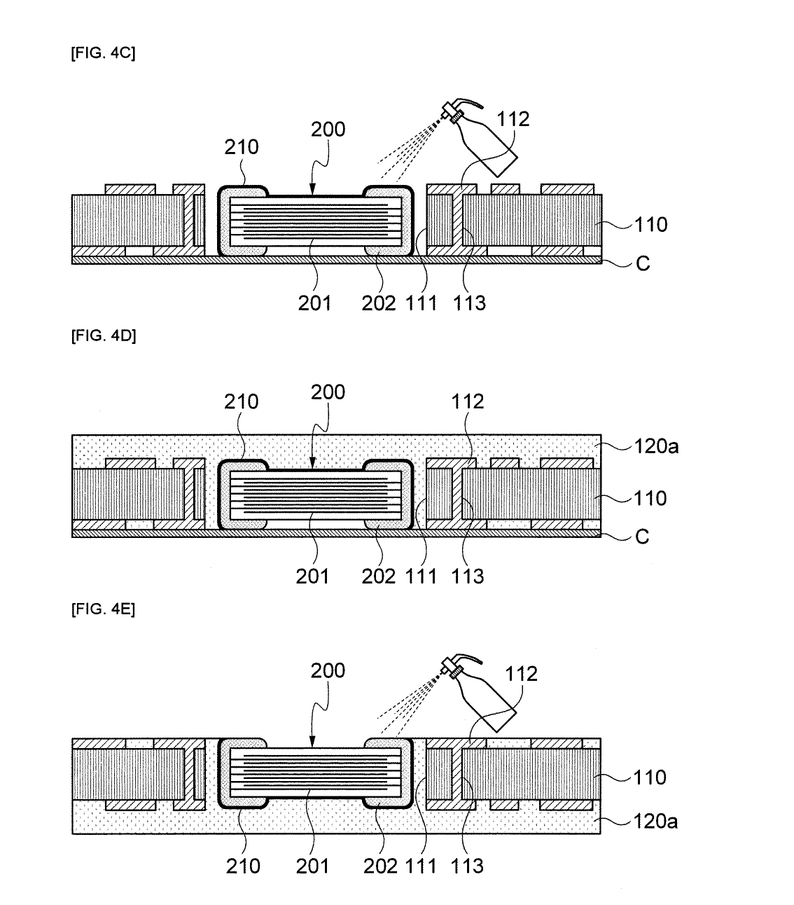

FIG. 4 is a process diagram showing a process of manufacturing an electronic component embedded printed circuit board in accordance with another embodiment of the present invention.

As shown, first, a cavity 111 is formed in a core 110, which is made of an insulating material, in the shape of a through hole. At this time, the conditions of formation or size of the cavity 111 may be equal to the core processing conditions in the embodiment shown in FIG. 3, and specific descriptions thereof will be omitted.

Next, a carrier C is attached to a lower surface of the core 110, and an electronic component 200 is inserted in the cavity 111 formed in the core 110 to be fixed on the carrier C. Here, the electronic component 200 inserted in the cavity 111 of the core 110 is an electronic component in which only external electrodes 202 are formed on both sides of a main body 201 and a bonding coating layer 210 is not formed on an outer peripheral surface.

After inserting the electronic component 200, a silane solution is applied on the electronic component 200 by spraying, printing, or dispensing. At this time, in FIG. 4c shown below, a spraying method is shown as a representative of the applying method of the silane solution but the applying method of the silane solution is not limited thereto. Further, since the silane solution is described in detail in the description of the embodiment of FIG. 3, specific descriptions thereof will be omitted in the description of the present embodiment. And, the silane solution applied on the electronic component 200 may be applied on an upper surface of the main body 201 of the electronic component 200 or applied to flow down to an upper surface and a side surface of the external electrode 202 including the upper surface of the main body 201 according to adjustment of the amount of spraying so that the bonding coating layer 210 is formed on some surfaces of the electronic component 200.

Next, as in FIG. 4d, an upper insulating layer 120a is formed on the core 110 in which the electronic component 200 is embedded. The upper insulating layer 120a may be formed by laminating an insulating material and cured by heating and compressing the insulating material. When heating and compressing the insulating material, some of the insulating material is introduced into a space between the cavity 111 of the core 110 and the electronic component 200 and cured to fix the electronic component 200.

After that, as in FIG. 4e, the carrier C attached to the core 110 is removed, the core 110 is reversed to expose the lower surface thereof, and the silane solution is applied on the surface of the electronic component 200 exposed on the cavity 111 of the core 110, where the bonding coating layer is not formed, by spraying etc. to form the bonding coating layer 210.

And, a lower insulating layer 120b is laminated on an opposite surface of the core 110 on which the upper insulating layer 120a is formed in the same manner as the upper insulating layer 120a and cured by heating and compression to form the upper and lower insulating layers 120a and 120b as in FIG. 4f.

Finally, as in FIG. 4g, a via hole 121 is formed in the upper and lower insulating layers 120a and 120b, a plating layer is formed inside the via hole 121 and on the insulating layers 120a and 120b, and a circuit pattern 130 is formed by etching the plating layer to complete the manufacture of the electronic component embedded printed circuit board.

Evaluation of Bonding Force of Electronic Component of Electronic Component Embedded Printed Circuit Board

Bonding reliability of the electronic component of the electronic component embedded printed circuit board manufactured as in FIG. 1 or 2 through the above manufacturing process is tested by the standard specifications. Looking into the results of the test, it is possible to understand that the adhesion with the insulating layer is reinforced and the bonding reliability is improved in the printed circuit board having the bonding coating layer on the outer peripheral surface of the electronic component than the printed circuit board without the bonding coating layer on the outer peripheral surface of the electronic component as below.

Evaluation of Adhesion Between Electronic Component and Insulating Layer

First, after prepreg (PPG), which is used as a representative material of the insulating layer 120 adhered to the electronic component 200 embedded in the electronic component embedded printed circuit board in accordance with the present invention, and the MLCC (electronic component), which has the bonding coating layer 210 on the outer peripheral surface, are bonded and the prepreg is cured to closely couple the insulating layer and the MLCC, evaluation is performed by applying a shear stress according to the standard specifications of JESD22-B117.

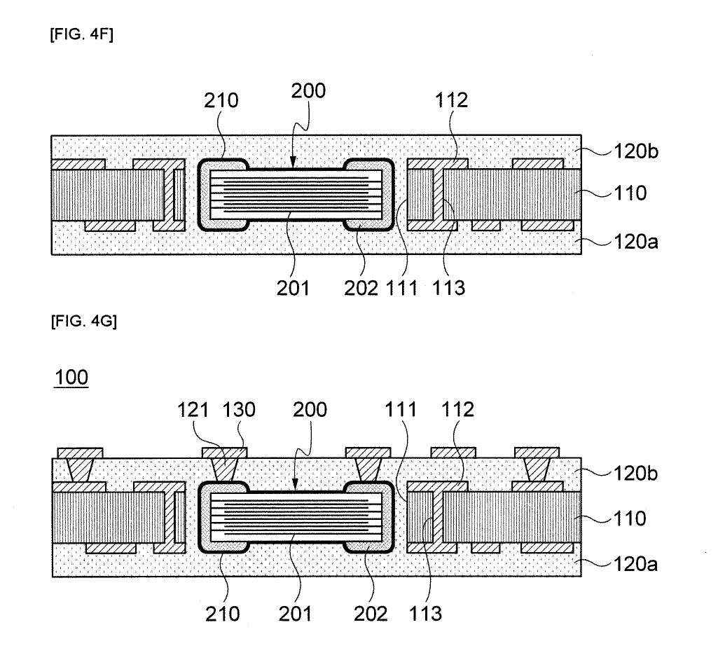

As the result of the evaluation by the above specifications, as shown in the graph of FIG. 5, a shear strength (a force when a bonded portion is separated by applying a shear stress to one side) in a state in which the MLCC without the bonding coating layer 210 is bonded on the cured prepreg is averagely 1293 kgf, and a shear strength in a state in which the MLCC having the bonding coating layer 210 formed on the outer peripheral surface using an amino silane solution is bonded on the cured prepreg is averagely 1828 kgf which is improved by about 41%.

Further, it is possible to understand that the shear strength of the MLCC having the bonding coating layer 210 formed by applying a silane solution in which epoxy silane or vinyl silane in addition to amino silane is mixed with ethanol is improved by about 20 to 30%.

Here, FIG. 5 is a graph of evaluation of adhesion between the electronic component and the insulating layer (prepreg) applied to the electronic component embedded printed circuit board in accordance with the present invention. In the adhesion evaluation, a silane solution in which amino silane, epoxy silane, or vinyl silane of which performance of improvement of adhesion with resin materials such as prepreg and epoxy constituting the insulating layer is mixed with ethanol at a predetermined ratio is used.

Evaluation of Bonding Reliability of Electronic Component Embedded in Printed Circuit Board

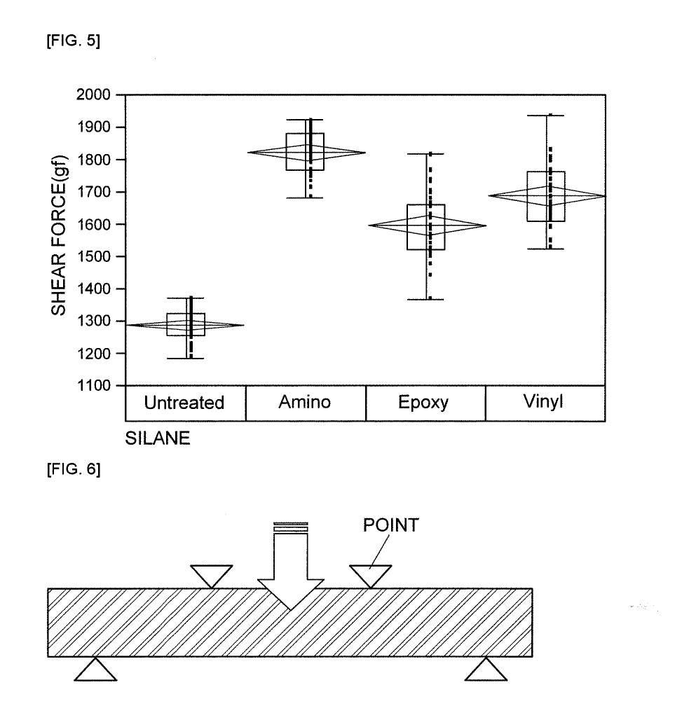

In the electronic component embedded printed circuit board manufactured through the manufacturing method of the present invention, evaluation of bonding reliability of the electronic component embedded in the substrate and the insulating layer is performed by a bending test according to JESD22-B113 standard specifications as shown in FIG. 6 when the manufacture of the printed circuit board is completed. The bending test of the printed circuit board is performed by applying pressure to four points through a commercial bending evaluation tester, pressing to a depth of 2 mm to generate warpage, and repeating bending 20000 times once per second at a frequency of 1 Hz, and the results are evaluated.

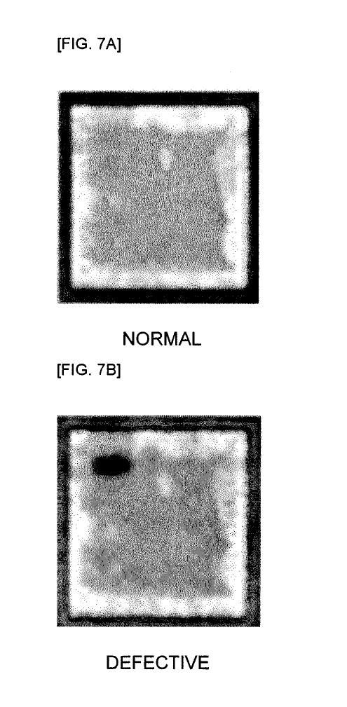

As the result of the evaluation by the above specifications, delamination of the electronic component 200 and the insulating layer 120 is checked through an ultrasonic microscope by comparing the printed circuit board in which the electronic component 200 having the bonding coating layer 210 is embedded with the printed circuit board in which the electronic component 200 without the bonding coating layer 210 is embedded. FIG. 7 shows comparison photographs of a normal product in which the electronic component and the insulating layer aren't delaminated and a defective product in which the electronic component and the insulating layer are delaminated after the bending test of the electronic component embedded printed circuit board. When the electronic component is delaminated from the insulating layer, the delamination position of the electronic component is identified as black like the picture on the right. Thus, the actual occurrence of the delamination between the electronic component and the insulating layer is checked through a cross-sectional analysis of the printed circuit board.

Further, as shown in Table 1, looking into the results of the bending test when the bonding coating layer is formed on the electronic component, when the bonding coating layer is not formed on the electronic component, and when the bonding coating layer is formed on the electronic component by spraying (another embodiment, corresponding to a process of FIG. 4), the bonding reliability is greatly improved in the two cases when the bonding coating layer is formed on the electronic component than the case when the bonding coating layer is not formed on the electronic component.

TABLE 1

| | | Number of |
|---|---|---|
| | | internal |
| | | delamination |
| Classification | Bending test | failures |
| Non-treatment of Bonding coating layer | 20000 times | 17/200 |
| Formation of bonding coating layer | 20000 times | 0/200 |
| by dipping (first embodiment) | | |
| Formation of bonding coating layer | 20000 times | 3/200 |
| by spraying (second embodiment) | | |

As described above, the electronic component embedded printed circuit board and the method for manufacturing the same in accordance with the present invention can improve bonding and adhesion performances of the insulating layers laminated on and under the core and the surface of the electronic component by forming the bonding coating layer on the surface of the electronic component embedded in the core to embed the electronic component, and can prevent substrate failures and improve the yield of the printed circuit board products by improving coupling performance of the insulating layer and the electronic component to prevent delamination and lifting of the insulating layer from the electronic component.

The above-described preferred embodiments of the present invention are disclosed for the purpose of exemplification and it will be appreciated by those skilled in the art that various substitutions, modifications and variations may be made in these embodiments without departing from the technical spirit of the present invention. Such substitutions and modifications are intended to be included in the appended claims.

What is claimed is:

1. An electronic component embedded printed circuit board comprising:
a core having a cavity;
an electronic component inserted in the cavity and having a bonding coating layer on an outer peripheral surface;
insulating layers laminated on and under the core and in contact with the bonding coating layer; and
circuit patterns provided on the insulating layers.

2. The electronic component embedded printed circuit board according to claim 1, wherein the electronic component is an MLCC comprising external electrodes provided on both sides and a main body provided between the external electrodes.

3. The electronic component embedded printed circuit board according to claim 2, wherein the bonding coating layer is formed over the entire surface along the external electrodes and the main body.

4. The electronic component embedded printed circuit board according to claim 2, wherein the bonding coating layer is formed on a surface of the main body except the external electrodes.

5. The electronic component embedded printed circuit board according to claim 1, wherein the bonding coating layer comprises a coupling agent interposed between different kinds of materials to reinforce a bonding force.

6. The electronic component embedded printed circuit board according to claim 5, wherein the coupling agent comprises silane containing silicon (Si) atoms and organic functional groups.

7. The electronic component embedded printed circuit board according to claim 6, wherein the silane comprises at least one selected from the group consisting of amino silane, epoxy silane, and vinyl silane.

8. The electronic component embedded printed circuit board according to claim 5, wherein the silane is used by being mixed with ethanol.

9. The electronic component embedded printed circuit board according to claim 1, further comprising:
a via formed inside the insulating layer to electrically connect the circuit pattern and the external electrode.

10. The electronic component embedded printed circuit board according to claim 1, wherein the insulating layer fills a space between the cavity and the electronic component.

11. The electronic component embedded printed circuit board according to claim 2, wherein circuit layers of a predetermined pattern are formed on upper and lower surfaces of the core to be electrically connected through a through hole.

12. A method for manufacturing an electronic component embedded printed circuit board, comprising:
forming a through hole-shaped cavity in a core and attaching a carrier to a lower surface of the core;
inserting an electronic component having a bonding coating layer on an outer peripheral surface in the cavity;
forming an upper insulating layer on the core in which the electronic component is embedded;
removing the carrier attached to the lower surface of the core;
forming a lower insulating layer on an opposite surface of the core on which the upper insulating layer is formed; and
forming circuit patterns on the upper and lower insulating layers to be electrically connected to the electronic component through a via.

13. The method for manufacturing an electronic component embedded printed circuit board according to claim 12, further comprising, before inserting the electronic component in the cavity, applying an adhesive member on an upper surface of the carrier.

14. The method for manufacturing an electronic component embedded printed circuit board according to claim 12, further comprising, before inserting the electronic component in the cavity, forming the bonding coating layer on the outer peripheral surface of the electronic component.

15. The method for manufacturing an electronic component embedded printed circuit board according to claim 14, wherein the bonding coating layer is formed only on a surface of a main body between external electrodes provided on both sides of the electronic component.

16. The method for manufacturing an electronic component embedded printed circuit board according to claim 14, wherein the bonding coating layer is formed to surround the outer peripheral surface including the external electrodes provided on the both sides of the electronic component and the surface of the main body.

17. The method for manufacturing an electronic component embedded printed circuit board according to claim 12, wherein the bonding coating layer comprises silane containing silicon atoms and organic functional groups.

18. The method for manufacturing an electronic component embedded printed circuit board according to claim 15, wherein the bonding coating layer is formed only on the surface of the main body by dipping the electronic component in a silane solution before the formation of the external electrodes.

19. The method for manufacturing an electronic component embedded printed circuit board according to claim 16, wherein the bonding coating layer is formed on the entire outer peripheral surface including the main body and the external electrodes by forming the external electrodes and dipping the electronic component in a silane solution.

20. A method for manufacturing an electronic component embedded printed circuit board, comprising:
forming a through hole-shaped cavity in a core and attaching a carrier to a lower surface of the core;
inserting an electronic component in the cavity;
forming a bonding coating layer on the electronic component inserted in the cavity;
forming an upper insulating layer on the core in which the electronic component is embedded in the cavity;
removing the carrier attached to the lower surface of the core;
forming the bonding coating layer on a surface of the electronic component exposed on the cavity of the core, where the bonding coating layer is not formed;
forming a lower insulating layer on an opposite surface of the core on which the upper insulating layer is formed; and
forming circuit patterns on the upper and lower insulating layers to be electrically connected to the electronic component through a via.

21. The method for manufacturing an electronic component embedded printed circuit board according to claim 20, wherein in forming the bonding coating layer on the electronic component, the bonding coating layer is formed by liquid application using one of spraying, printing, and dispensing.

22. The method for manufacturing an electronic component embedded printed circuit board according to claim 20, wherein the bonding coating layer comprises silane containing silicon atoms and organic functional groups.

23. The method for manufacturing an electronic component embedded printed circuit board according to claim 21, wherein in forming the bonding coating layer on the electronic component, the bonding coating layer is applied on an upper surface of a main body of the electronic component or applied on an upper surface and a side surface of an external electrode including the upper surface of the main body of the electronic component by adjustment of the amount of spraying of a silane solution.

24. The method for manufacturing an electronic component embedded printed circuit board according to claim 20, wherein in forming the bonding coating layer on the surface of the electronic component where the bonding coating layer is not formed, the bonding coating layer is formed by liquid application using one of spraying, printing, and dispensing.
